(19) United States
(12) Patent Application Publication
(10) Pub. No.: US 2014/0167749 A1
(43) Pub. Date: Jun. 19, 2014

(54) HALL SENSOR AND METHOD OF MANUFACTURING THE SAME

(71) Applicant: SAMSUNG ELECTRO-MECHANICS CO., LTD., Suwon (KR)

(72) Inventors: Boum Seock Kim, Suwon (KR); Eun Tae Park, Suwon (KR); Se Hoon Jeong, Suwon (KR); Sung Ho Lee, Suwon (KR)

(73) Assignee: SAMSUNG ELECTRO-MECHANICS CO., LTD., Suwon (KR)

(21) Appl. No.: 13/831,712

(22) Filed: Mar. 15, 2013

(30) Foreign Application Priority Data
Dec. 14, 2012 (KR) 10-2012-0146562

(51) Int. Cl. H01L 43/14; G01V 3/08

(52) U.S. Cl. CPC H01L 43/14; G01V 3/08
USPC 324/251; 438/3

(57) ABSTRACT

Disclosed herein are a Hall sensor and a method of manufacturing the Hall sensor. The Hall sensor includes: a flexible substrate in which a groove is formed; a magnetic field flux concentrator formed in the groove of the flexible substrate; an electrode that is patterned to contact the magnetic field flux concentrator; a passivation layer formed around the electrode; and a sensor layer stacked on the passivation layer.

### CROSS REFERENCE TO RELATED APPLICATION

This application claims the benefit of Korean Patent Application No. 10-2012-0146562, filed on Dec. 14, 2012, entitled “Hall Sensor and Method of Manufacturing the Same”, which is hereby incorporated by reference in its entirety into this application.

### BACKGROUND OF THE INVENTION

1. Technical Field

The present invention relates to a Hall sensor and a method of manufacturing the same.

2. Description of the Related Art

A geomagnetic sensor marks a direction by measuring an earth's magnetic field which is one of the fine magnetic fields. A direction measuring method by measuring an earth's magnetic field which is one of the fine magnetic fields is based on measurement of a three-axis component of an earth's magnetic field at a position horizontal to an earth's surface.

A magnetic field detecting method used in the above fine magnetic field detection sensor is, for example, a fluxgate method, a magnetic resistance (MR) method, a magnetic impedance (MI) method, and a Hall effect method.

Here, manufacturing methods for the fluxgate method, the MR method, and the MI method are difficult, and it is difficult to manufacture a Hall sensor in a small size compared to the Hall effect method. Thus, the Hall effect method is widely used in geomagnetic sensors for mobile devices.

According to the Hall effect method, when an electron receives a Lorentz force with respect to an external magnetic field, the electron bends according to the external force, and a variation in a voltage is generated due to the bent electron. The intensity of the external magnetic field is predicted by measuring the generated voltage variation.

Examples of materials for forming a Hall sensor using the Hall effect as described above are, in general, Si, InAs, InSb, and GaAs. Among these, when Si is used as a constituent material, a sensor device may be manufactured, and at the same time a circuit may be manufactured by using a CMOS process, and thus Si is currently mostly used.

However, when Si is used, magnetic sensitivity thereof is very low compared to other constituent materials, and a sensitivity that is 100 times lower compared to other methods such as the fluxgate method, MI method, and MR method is exhibited.

Accordingly, the current technology aims at increasing sensitivity of a Hall geomagnetic sensor by using Si which allows an easy manufacture, mass production, and reduction in the size of the Hall sensor.

Meanwhile, it is highly likely that a flexible device is required in next-generation mobile terminals. Accordingly, a technique of manufacturing each component to be flexible will be inevitably necessary.

Also in the case of the geomagnetic sensor, in order to make the same flexible, a Hall element (Si, InSb, or GaAs) is deposited on a polymer substrate, and in this case, since a polymer is not a rigid substrate, the characteristics of the Hall element deposited on the polymer substrate are worse than when a Hall element is deposited on a rigid substrate.

According to a method of manufacturing a flexible geomagnetic sensor according to the conventional art, a Hall element such as Si, InSb, or GaAs is deposited on a flexible substrate formed of a polymer, and then an upper electrode is formed thereon by patterning, and the resultant product is passivated.

However, according to the conventional art, when forming a flexible device, unlike primarily depositing a Hall element on a rigid substrate, a substrate itself is flexible, and also, a material of the substrate is a polymer that is different from a material that is to be deposited on the substrate. Consequently, crystallinity of the Hall element is not good, and the characteristics thereof are degraded compared to when a Hall element is deposited on a rigid substrate.

Also, due to a high deposition temperature, it is difficult for a flexible substrate to withstand a high temperature, and thus the entire processes have to be completed at a temperature lower than 450° C. Due to these reasons, desired characteristics of a flexible Hall sensor device are not fulfilled.

### SUMMARY OF THE INVENTION

The present invention has been made in an effort to provide a Hall sensor that is formed by depositing a Hall element on a rigid substrate and by mounting the completed Hall element on a flexible substrate, and a method of manufacturing the Hall sensor.

According to a first preferred embodiment of the present invention, there is provided a Hall sensor including: a flexible substrate in which a groove is formed; a magnetic field flux concentrator formed in the groove of the flexible substrate; an electrode that is patterned to contact the magnetic field flux concentrator; a passivation layer formed around the electrode; and a sensor layer stacked on the passivation layer.

The Hall sensor may further include a molding layer surrounding the passivation layer and the sensor layer.

The flexible substrate may be formed of one material selected from the group consisting of polyethylene terephthalate (PET), polyethylene sulfide (PES), polyethylene naphthalate (PEN), polycarbonate (PC), nylon, polyether ether ketone (PEEK), polysulfone (PSF), polyetherimide (PEI), polyacrylate (PAR), polybutylene terephthalate (PBT), and ARTON formed of a norbonene resin having a polarity.

The sensor layer may include: a first compound semiconductor layer formed of at least two elements selected from the group consisting of Ga, Al, In, As, Sb, and P; and a second compound semiconductor layer that is formed between the passivation layer and the first compound semiconductor layer, is formed of InxGa1-xAsySb1-y (0<x≦1.0, 0≦y≦1.0), and functions as a functional layer.

According to a second preferred embodiment of the present invention, there is provided a method of manufacturing a Hall sensor, the method including: (A) forming a sensor device including a sacrificial layer disposed on a carrier substrate; (B) preparing a flexible substrate including a magnetic field flux concentrator; (C) mounting the sensor device on the flexible substrate such that the sensor device faces the flexible substrate; and (D) removing the carrier substrate and the sacrificial layer.

The operation (A) may include: (A-1) forming the sacrificial layer on the carrier substrate; (A-2) forming a sensor layer on the sacrificial layer; (A-3) forming an electrode on the sensor layer; and (A-4) forming a passivation layer on the sensor layer.

The carrier substrate may be a rigid substrate and is formed of MgO or Al₂O₃.

Operation (A-2) may include: forming a first compound semiconductor layer formed of at least two elements selected from the group consisting of Ga, Al, In, As, Sb, and P; and forming a second compound semiconductor layer that is formed on the first compound semiconductor layer, is of InxGa1-xAsySb1-y (0<x≦1.0, 0≦y≦1.0), and functions as a functional layer.

Operation (B) may include: (B-1) preparing a mold in which a groove corresponding to the flexible substrate is formed; (B-2) locating a magnetic field flux concentrator in a center of the groove formed in the mold; (B-3) filling a solution for a flexible substrate in the groove of the mold; and (B-4) hardening the solution for a flexible substrate and separating the mold to complete the flexible substrate.

Operation (D) may include: (D-1) attaching the carrier substrate on the flexible substrate and irradiating laser on the carrier substrate; (D-2) separating the sacrificial layer and the carrier substrate; and (D-3) removing the sacrificial layer.

The sacrificial layer may be formed of one material selected from the group consisting of a GaO based material, a GaN based material, a GaON based material, lead zirconate titanate (PZT), and ZrO₂.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a Hall sensor according to an embodiment of the present invention;

FIGS. 2 through 10 are views illustrating a method of manufacturing a Hall sensor according to an embodiment of the present invention; and

FIGS. 11 through 14 are views illustrating a method of manufacturing a flexible substrate on which a magnetic field flux concentrator provided in the operation illustrated in FIG. 7 is formed.

### DESCRIPTION OF THE PREFERRED EMBODIMENTS

The objects, features, and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

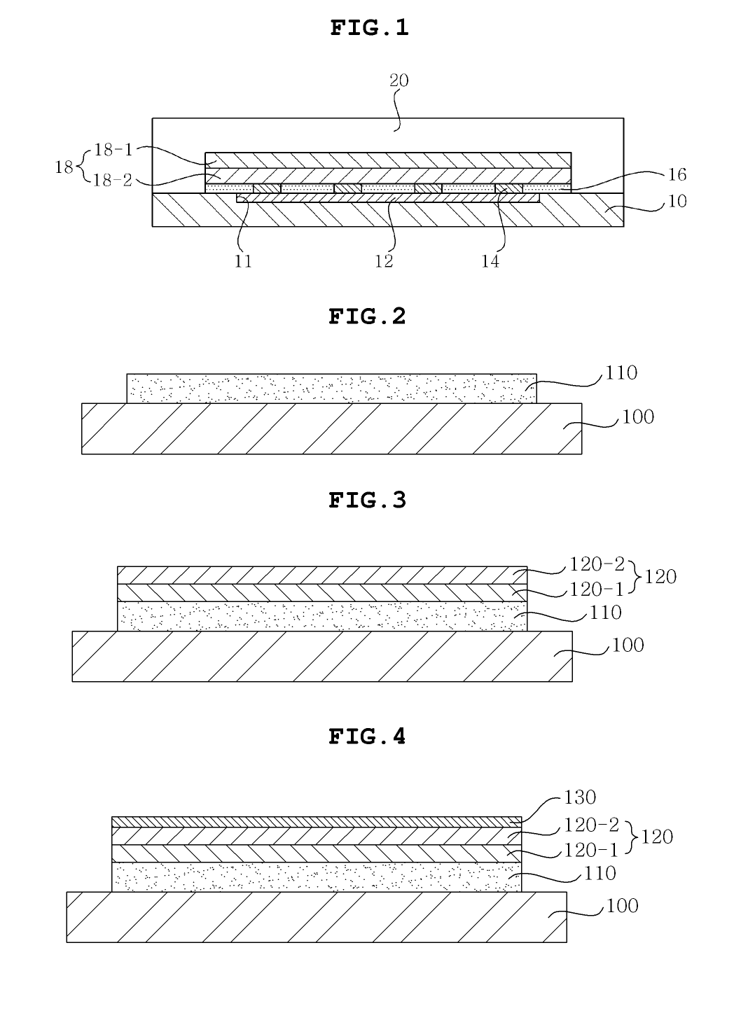

FIG. 1 is a cross-sectional view of a Hall sensor according to an embodiment of the present invention.

Referring to FIG. 1, the Hall sensor according to the current embodiment of the present invention includes a flexible substrate 10 in which a groove (11) is formed, a magnetic field flux concentrator 12 which is formed in the groove (11) of the flexible substrate 10, an electrode 14 that is stacked on the magnetic field flux concentrator 12 and is patterned, a passivation layer 16 formed around the electrode 14, a sensor layer 18 that is stacked on the passivation layer 16, and a molding layer 20 surrounding the passivation layer 16 and the sensor layer 18.

The flexible substrate 10 is a substrate having flexibility and includes a polymer.

Here, a polymer refers to both a thermosetting resin and a thermal reinforced resin, and preferably, the flexible substrate 10 is characterized in that it is a thermosetting resin that is hardened when heat is applied thereto and has flexibility. Depending on the fields to which the present invention is applied, a polymer selected from the group consisting of polyethylene terephthalate (PET), polyethylene sulfide (PES), polyethylene naphthalate (PEN), polycarbonate (PC), nylon, polyether ether ketone (PEEK), polysulfone (PSF), polyetherimide (PEI), polyacrylate (PAR), polybutylene terephthalate (PBT), and ARTON formed of a norbonene resin having a polarity may be used the polymer.

The flexible substrate 10 has a thickness of 150 to 300 μm, preferably, 100 μm.

A groove 11 is formed in an upper portion of the flexible substrate 10 to mount the magnetic field flux concentrator 12.

Next, the magnetic field flux concentrator 12 is mounted in the groove 11 of the flexible substrate 10 so that a magnetic field is concentrated on the sensor layer 18 to increase sensitivity of the Hall sensor.

Meanwhile, the passivation layer 16 is disposed between the magnetic field flux concentrator 12 and a sensor device (formed of an electrode 14 and the sensor layer 18), and surrounds the electrode 14 of the sensor device to protect the electrode 14 from the external environments.

The passivation layer 16 may preferably be formed of SiN, SiON, or SiO₂.

Meanwhile, the electrode 14 is disposed between the magnetic field flux concentrator 12 and the sensor layer 18, and is usually an ohmic electrode, and may preferably be in ohmic contact with the sensor layer 18. The electrode 14 may be formed of a multi-layer electrode such as AuGe/Ni/Au that is well-known in the art, and may also be formed of a single-layer metal.

In addition, the sensor layer 18 includes a second compound semiconductor layer 18-2 that is formed of InxGa1-xAsySb1-y (0<x≦1.0, 0≦y≦1.0) on the passivation layer 16.

In addition, a first compound semiconductor layer 18-1 formed of at least two elements selected from the group consisting of Ga, Al, In, As, Sb, and P on the second compound semiconductor layer 18-2.

(111) surfaces of the first compound semiconductor layer 18-1 and the second compound semiconductor layer 18-2 are formed to be parallel to a surface of the magnetic field flux concentrator 12.

The first compound semiconductor layer 18-1 is formed of a compound semiconductor formed of at least two elements selected from the group consisting of Ga, Al, In, As, Sb, and P, and generally has a thickness of 0.01 μm to 10 μm, preferably, 0.1 μm to 5 μm, and more preferably, 0.5 μm to 2 μm. Al1-zGazAs (0≦z≦1) is a preferable example for the material for the first compound semiconductor layer 18-1, and GaAs is particularly preferable.

Also, the second compound semiconductor layer 18-2 is formed of InxGa1-xAsySb1-y (0≦y≦1), and generally has a thickness of 0.1 μm; if the thickness is thicker, sheet resistance is reduced. When forming a sensor device having a high sensitivity and a relatively high resistance, the thickness of the second compound semiconductor layer 18-2 is generally 0.15 μm to 2 μm, preferably, 0.3 μm to 1.5 μm, and more preferably, 0.5 μm to 1.2 μm. InAsySb1-y (0≦y≦1) is a preferable example as the material for the second compound semiconductor layer 18-2, and InSb or InAs is particularly preferable.

Also, the second compound semiconductor layer 18-2 may also be doped with impurities. Preferable examples of a doping element are Si and Sn. A concentration of the impurities may be generally 1×E15/cm³ to 3.5×E16/cm³, preferably, 2.5×E15/cm³ to 2.5×E16/cm³, and more preferably, 5×E15/cm³ to 2×E16/cm³.

Meanwhile, the molding layer 20 is formed to surround the sensor layer 18, the passivation layer 16, and an exposed portion of the flexible substrate 10.

According to the Hall sensor configured as described above, the sensor device may be deposited on a rigid substrate on the flexible substrate 10 at a high temperature, and thus performance of the sensor device may be enhanced.

Also, according to the present invention, when manufacturing the flexible substrate 10, the magnetic field flux concentrator 12 may be formed in advance when hardening a polymer, and thus the manufacturing process may be simplified.

In addition, according to the present invention, as a passivation layer for surrounding the magnetic field flux concentrator 12 is not necessary, costs may be reduced and the process may be simplified.

FIGS. 2 through 10 are views illustrating a method of manufacturing a Hall sensor according to an embodiment of the present invention.

Referring to FIG. 2, first, a sacrificial layer 110 is deposited on a carrier substrate 100.

Here, the carrier substrate 100 allows to stably deposit a sensor device, and then, when the sensor device is mounted on a flexible substrate, the carrier substrate 100 is to be removed by using a laser lift off method, and a rigid substrate is formed of MgO or Al₂O₃.

In addition, the sacrificial layer 110 is used to separate the carrier substrate 100 from the sensor device when the manufacture of the sensor device is completed. The sacrificial layer 110 may be formed by using a chemical vapor deposition (CVD) method or a physical vapor deposition (PVD) method. Preferably, the sacrificial layer 110 may be formed by using a sputtering method, which is one kind of PVD method.

The sacrificial layer 110 may be formed of a material that is capable of absorbing various types of excimer lasers having a wavelength of 157 nm to 350 nm and is a non-conductor material such as a GaO, GaN, or GaON based material, or lead zirconate titanate (PZT), ZrO₂, and preferably, the sacrificial layer 110 may be formed of GaON.

Next, as illustrated in FIG. 3, a sensor layer 120 formed of the first compound semiconductor layer 120-1 and the second compound semiconductor layer 120-2 is formed on the sacrificial layer 110.

In further detail, the first compound semiconductor layer 120-1 is formed of GaAs on the sacrificial layer 110 to a thickness of 700 nm and the second compound semiconductor layer 120-2 is formed of InSb also thereon to a thickness of 1 μm. The first compound semiconductor layer 120-1 is formed of a compound semiconductor formed of at least two elements selected from the group consisting of Ga, Al, In, As, Sb, and P, and generally has a thickness of 0.01 μm to 10 μm, preferably, 0.1 μm to 5 μm, and more preferably, 0.5 μm to 2 μm. Al1-zGazAs (0≦z≦1) is a preferable example for the material for the first compound semiconductor layer 120-1, and GaAs is particularly preferable.

Also, the second compound semiconductor layer 120-2 is formed of InxGa1-xAsySb1-y (0≦y≦1), and generally has a thickness of 0.1 μm; if the thickness is thicker, sheet resistance is reduced. When forming a sensor device having high sensitivity and relatively high resistance, the thickness of the second compound semiconductor layer 120-2 is generally 0.15 μm to 2 μm, preferably, 0.3 μm to 1.5 μm, and more preferably, 0.5 μm to 1.2 μm. InAsySb1-y (0≦y≦1) is a preferable example as the material for the second compound semiconductor layer 120-2, and InSb or InAs is particularly preferable.

Also, the second compound semiconductor layer 120-2 may also be doped with impurities. Preferable examples of a doping element are Si and Sn. A density of the impurities may be generally 1×E15/cm³ to 3.5×E16/cm³, preferably, 2×E15/cm³ to 2.5×E16/cm³, and more preferably, 5×E15/cm³ to 2×E16/cm³.

The sensor layer 120 may be formed by using a CVD method or a PVD method. Preferably, the sensor layer 120 may be formed by using a sputtering method, which is one kind of the PVD method.

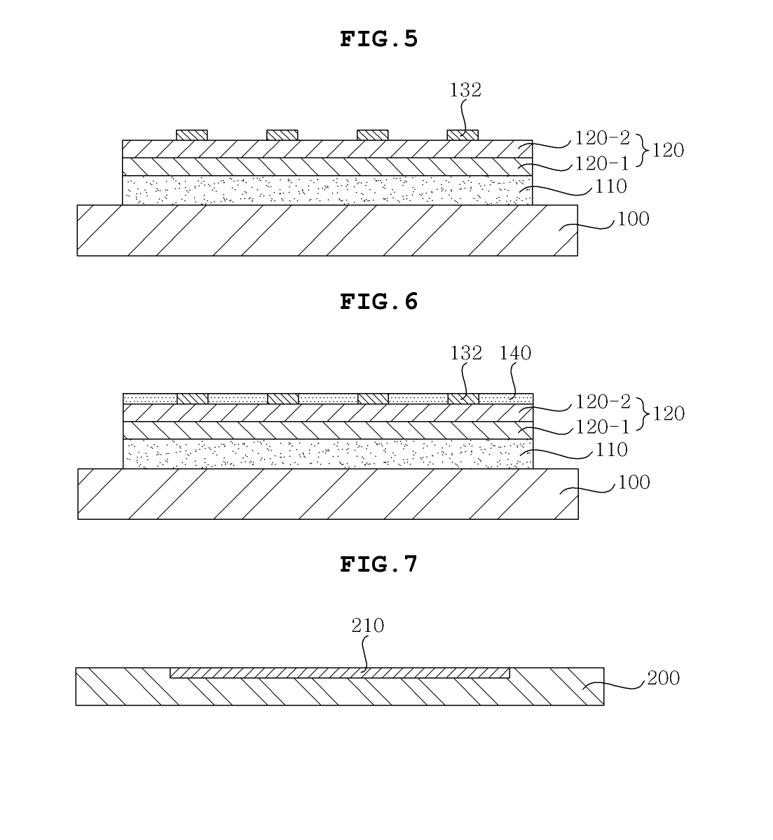

Next, as illustrated in FIG. 4, an electrode layer 130 is formed on the sensor layer 120 using a plating method or the like, and as illustrated in FIG. 5, a mask is used to pattern (the electrode layer 130) to form a patterned electrode 132.

The electrode may be formed of a multi-layer electrode such as AuGe/Ni/Au which is well-known in the art, or may also be a single-layer metal.

Next, as illustrated in FIG. 6, in order to protect the patterned electrode 132, a passivation layer 140 is deposited.

The passivation layer 140 may preferably be formed of SiN, SiON, or SiO₂.

The passivation layer 140 may be formed by using a CVD method or a PVD method. Preferably, the passivation layer 140 may be formed by using a sputtering method which is one kind of PVD method.

Meanwhile, during the above operation, a flexible substrate 200 is additionally or simultaneously prepared.

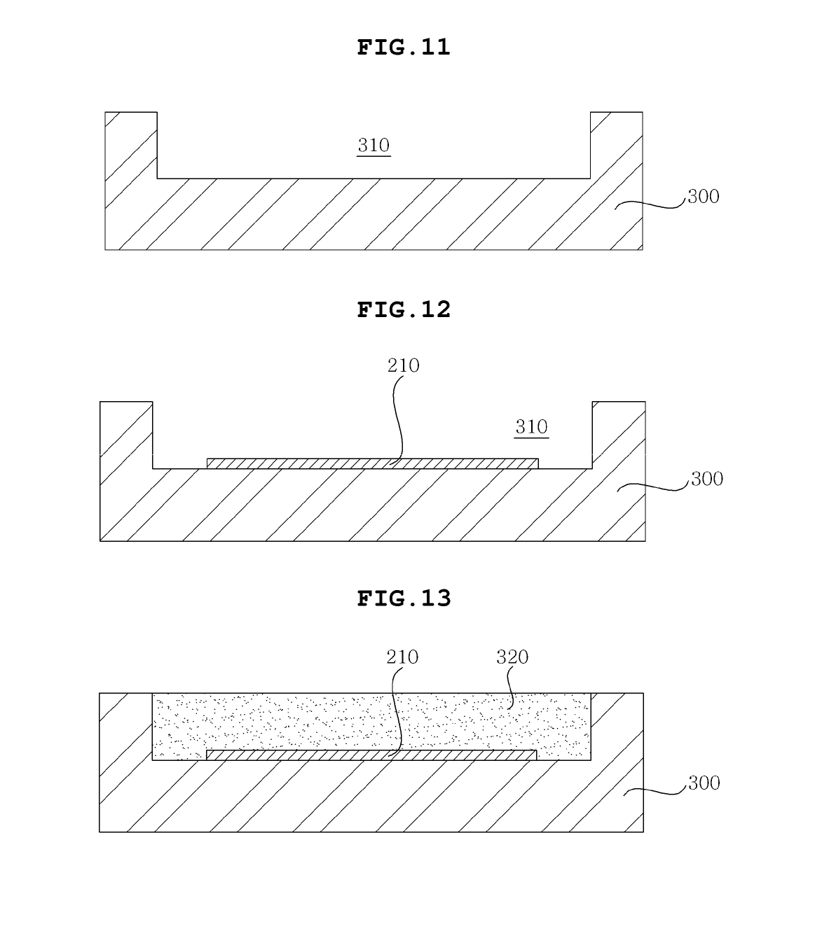

Here, as illustrated in FIG. 7, a groove is formed in the prepared flexible substrate 200, and a magnetic field flux concentrator 210 is included in the groove. A formation process thereof will be described in detail below with reference to FIGS. 11 through 14.

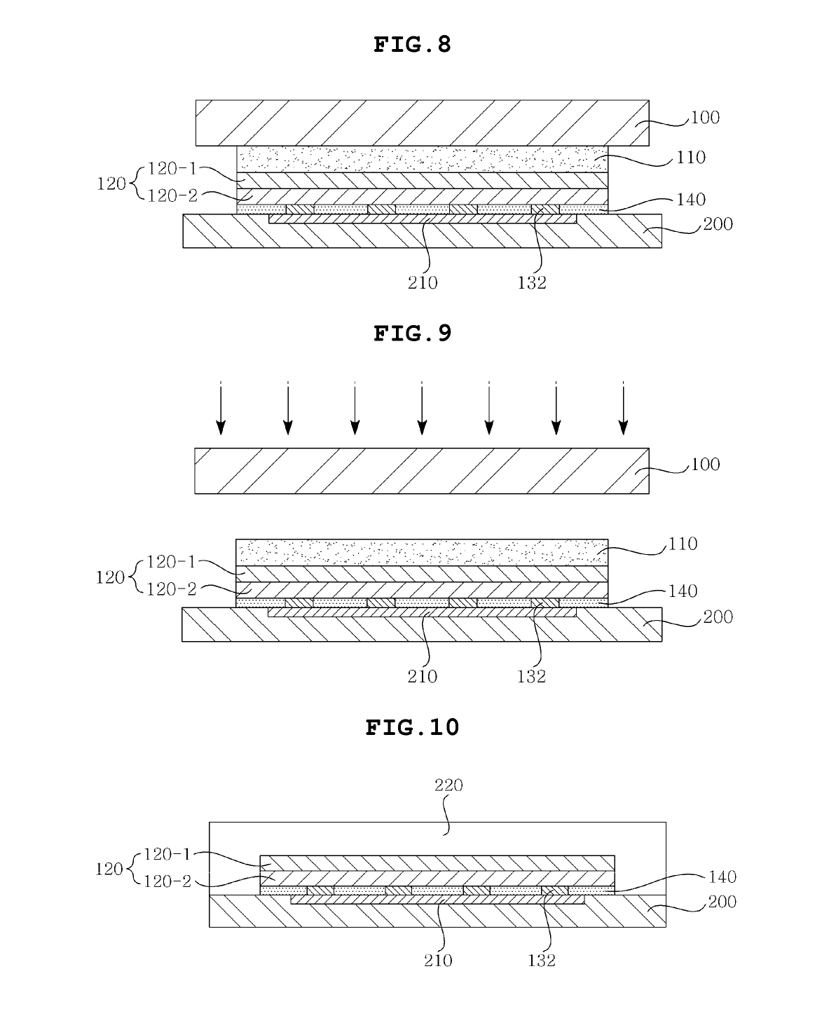

Next, as illustrated in FIG. 8, a surface of the Hall sensor on which the electrode 132 is formed is placed to face the flexible substrate 200, and then, the sensor device formed on the carrier substrate 100 (the sensor device includes a sensor layer and an electrode) is bonded to the flexible substrate.

Next, as illustrated in FIG. 9, a laser such as ArF, KrCl, KrF, XeCl, or XeF is irradiated to separate an interface between the carrier substrate 100 and the sacrificial layer 110. When a laser is irradiated on the carrier substrate 100, an energy band gap of the carrier substrate 100 is greater than a wavelength of the laser, and accordingly, the irradiated laser may easily pass through the carrier substrate 100 to be absorbed by the sacrificial layer 110. When the laser is irradiated, plasma is generated between the carrier substrate 100 and the sacrificial layer 110, and the plasma having a high temperature increases a temperature of the interface between the carrier substrate 100 and the sacrificial layer 110, thereby setting the sacrificial layer 110 in a partially melted state.

Here, in addition to the partial melting due to the high temperature of the plasma, a nitrogen (N₂) gas is generated, and gasification of the nitrogen gas exfoliates the interface between the carrier substrate 100 and the sacrificial layer 110. Preferably, when forming the sacrificial layer 110, a reactive hydrogen gas 112 may be injected when forming the sacrificial layer 110, and in a laser lift off operation, partial melting of the sacrificial layer 110 according to the high temperature of the plasma generates nitrogen gas N₂, and according to gasification of the hydrogen gas H2, the interface between the sacrificial layer 110 and the carrier substrate 100 is furthermore easily exfoliated.

As described above, when the sacrificial layer 110 is separated from the carrier substrate 100, as illustrated in FIG. 10, the sacrificial layer 110 attached on the sensor device is completely removed by ion milling, thereby completing the Hall sensor. Thereafter, the Hall sensor may be molded by coating a molding layer 220.

The Hall sensor that is completed as described above may have not only high sensor performance compared to other devices; moreover, when bonding a magnetic field flux concentrator, the magnetic field flux concentrator may also be easily fixed by hardening when manufacturing a flexible substrate. Accordingly, the Hall sensor may have far better workability compared to a flexible device according to the conventional art.

Meanwhile, FIGS. 11 through 14 are views illustrating a method of manufacturing a flexible substrate on which the magnetic field flux concentrator 210 provided in FIG. 8 is formed.

Referring to FIG. 11, first, a mold 300 including a groove 310 corresponding to the flexible substrate 200 is provided.

Next, as illustrated in FIG. 12, the magnetic field flux concentrator 210 is installed to be located in a center of the groove 310 of the mold 300.

Then, as illustrated in FIG. 13, a solution 320 for a flexible substrate is injected into the groove 310 of the mold 300 so as to fill the groove 310.

Here, the solution for a flexible substrate may include a polymer, and the polymer refers to both a thermosetting resin and a thermal reinforced resin; preferably, the polymer is characterized in that it is a thermosetting resin that is hardened when heat is applied thereto and has flexibility. Depending on the fields to which the present invention is applied, a polymer selected from the group consisting of polyethylene terephthalate (PET), polyethylene sulfide (PES), polyethylene naphthalene (PEN), polycarbonate (PC), nylon, polyether ether ketone (PEEK), polysulfone (PSF), polyetherimide (PEI), polyacrylate (PAR), polybutylene terephthalate (PBT), and ARTON formed of a norbonene resin having a polarity may be used as the polymer.

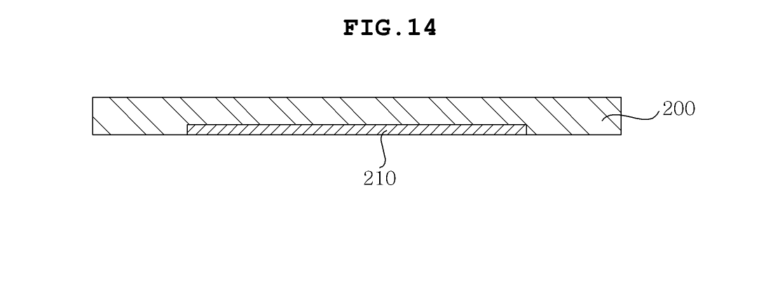

Then, as illustrated in FIG. 14, after the solution 320 for a flexible substrate is hardened, the mold 300 is separated to obtain the flexible substrate 200 in which the magnetic field flux concentrator 210 is buried.

According to the present invention, the sensor device may be deposited on a rigid substrate at a high temperature, and thus, performance of the sensor device may be enhanced.

Also, according to the present invention, when manufacturing the flexible substrate, as the magnetic field flux concentrator may be formed in advance when hardening a polymer, the manufacturing process may be simplified.

In addition, according to the present invention, as a passivation layer for surrounding the magnetic field flux concentrator is not necessary, costs may be reduced and the process may be simplified.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A Hall sensor comprising:
a flexible substrate in which a groove is formed;
a magnetic field flux concentrator formed in the groove of the flexible substrate;
an electrode that is patterned to contact the magnetic field flux concentrator;
a passivation layer formed around the electrode; and
a sensor layer stacked on the passivation layer.

2. The Hall sensor as set forth in claim 1, further comprising a molding layer surrounding the passivation layer and the sensor layer.

3. The Hall sensor as set forth in claim 1, wherein the flexible substrate is formed of one material selected from the group consisting of polyethylene terephthalate (PET), polyethylene sulfide (PES), polyethylene naphthalate (PEN), polycarbonate (PC), nylon, polyether ether ketone (PEEK), polysulfone (PSF), polyetherimide (PEI), polyacrylate (PAR), polybutylene terephthalate (PBT), and ARTON formed of a norbonene resin having a polarity.

4. The Hall sensor as set forth in claim 1, wherein the sensor layer includes:
a first compound semiconductor layer formed of at least two elements selected from the group consisting of Ga, Al, In, As, Sb, and P; and
a second compound semiconductor layer that is formed between the passivation layer and the first compound semiconductor layer, is formed of InxGa1-xAsySb1-y (0<x≦1.0, 0≦y≦1.0), and functions as a functional layer.

5. A method of manufacturing a Hall sensor, the method comprising:
(A) forming a sensor device including a sacrificial layer disposed on a carrier substrate;
(B) preparing a flexible substrate including a magnetic field flux concentrator;
(C) mounting the sensor device on the flexible substrate such that the sensor device faces the flexible substrate; and
(D) removing the carrier substrate and the sacrificial layer.

6. The method as set forth in claim 5, wherein the operation (A) includes:
(A-1) forming the sacrificial layer on the carrier substrate;
(A-2) forming a sensor layer on the sacrificial layer;
(A-3) forming an electrode on the sensor layer; and
(A-4) forming a passivation layer on the sensor layer.

7. The method as set forth in claim 5, wherein the carrier substrate is a rigid substrate and is formed of MgO or Al₂O₃.

8. The method as set forth in claim 5, wherein the operation (A-2) includes:
forming a first compound semiconductor layer formed of at least two elements selected from the group consisting of Ga, Al, In, As, Sb, and P; and
forming a second compound semiconductor layer that is formed on the first compound semiconductor layer, is of InxGa1-xAsySb1-y (0<x≦1.0, 0≦y≦1.0), and functions as a functional layer.

9. The method as set forth in claim 5, wherein the operation (B) includes:
(B-1) preparing a mold in which a groove corresponding to the flexible substrate is formed;
(B-2) locating a magnetic field flux concentrator in a center of the groove formed in the mold;
(B-3) filling a solution for a flexible substrate in the groove of the mold; and
(B-4) hardening the solution for a flexible substrate and separating the mold to complete the flexible substrate.

10. The method as set forth in claim 5, wherein the operation (D) includes:
(D-1) attaching the carrier substrate on the flexible substrate and irradiating laser on the carrier substrate;
(D-2) separating the sacrificial layer and the carrier substrate; and
(D-3) removing the sacrificial layer.

11. The method as set forth in claim 5, wherein the sacrificial layer is formed of one material selected from the group consisting of a GaO based material, a GaN based material, a GaON based material, lead zirconate titanate (PZT), and ZrO₂.
